(19) United States
(12) Patent Application Publication
(10) Pub. No.: US 2006/0075836 A1
(43) Pub. Date: Apr. 13, 2006

(54) Pressure sensor and method of operation thereof

(76) Inventors: Anis Zribi, Rexford, NY (US); Luana Emiliana Iorio, Clifton Park, NY (US); Daniel Joseph Lewis, Delmar, NY (US)

Correspondence Address: Patrick S. Yoder;FLETCHER YODER, P.O. Box 692289, Houston, TX, 77269-2289, US

(21) Appl. No.: 10/964,067

(22) Filed: Oct. 13, 2004

(51) Int. Cl. G01D 5/12; G01L 9/12; G01R 3/00

(52) U.S. Cl. 73/866.1; 29/595; 73/724

(57) ABSTRACT

A sensor for measuring an input signal is provided. The sensor includes a transducer having a soft magnetic material. The transducer may be disposed on a spring element. The soft magnetic material produces a change in impedance when the transducer is stimulated by the input signal. The impedance change is representative of a magnitude of the input signal. The sensor further includes a circuit coupled to the transducer, which is operable to measure the impedance change to determine the magnitude of the input signal. A method of operating the sensor is also provided.

### BACKGROUND

The invention relates generally to sensors, and more particularly, to high sensitivity pressure sensors fabricated using soft magnetic materials.

Pressure sensors are used in a wide range of industrial and consumer applications. Bourdon-tube type, diaphragm based, and strain gauge based pressure sensors can measure pressures across many orders of magnitude. A variation of the diaphragm-based pressure sensor is a cantilever-based pressure sensor that may be constructed by micro-machining techniques.

Several sensing techniques and devices have been developed for specific pressure sensing applications. Although attempts have been made to improve desirable sensor properties, such as high sensitivity, high stability, linearity, low hysteresis, high reliability, fast response and long lifetime, sensors typically suffer from limitations regarding one or more of the aforementioned properties.

Furthermore, micro-machined pressure sensors may include cavities filled with oil or other substances for transferring the pressure to the sensing element. Such pressure sensors are costly to manufacture and have limited ranges of operation.

It would therefore be desirable to develop a pressure sensor that exhibits high sensitivity to changes in pressure, high stability, linearity, low hysteresis, high reliability, relatively fast response and long life while reducing the need for packaging that is expensive or difficult to manufacture.

### SUMMARY

According to one aspect of the present technique, a sensor for measuring an input signal is provided. The sensor includes a transducer having a soft magnetic material. The transducer may be disposed on a spring element. The soft magnetic material undergoes a change in its impedance when the transducer is stimulated by the input signal. The impedance change is representative of a magnitude of the input signal. The sensor further includes a circuit coupled to the transducer that is operable to measure the impedance change to determine the magnitude of the input signal. A method of operating the sensor is also provided.

In accordance with another aspect of the present technique, a sensor for measuring an input signal is provided. The sensor comprises a transducer having a soft magnetic material that exhibits stress-impedance properties. The soft magnetic material is disposed on a spring element. The spring element is operable to resonate at a resonant frequency in absence of the input signal and to resonate at a responsive frequency upon being stimulated by the input signal. The sensor also includes a circuit coupled to the transducer that is operable to measure magnitude of shift in the resonant frequency to the responsive frequency. The magnitude of shift in the resonant frequency to the responsive frequency represents a magnitude of the input signal.

### BRIEF DESCRIPTION OF THE DRAWINGS

These and other features, aspects, and advantages of the present invention will become better understood when the following detailed description is read with reference to the accompanying drawings in which like characters represent like parts throughout the drawings.

FIG. 1 is a cross-sectional view of a pressure sensor with a cantilever-based capacitive pressure sensing mechanism constructed in accordance with an exemplary embodiment of the invention.

FIG. 2 is a cross-sectional view of a vertical diaphragm pressure sensor array illustrating measurement of pressure using soft magnetic material transducers, constructed in accordance with an exemplary embodiment of the invention.

FIG. 3 is a cross-sectional view of the vertical diaphragm pressure sensor array of FIG. 2 taken along line III-III of FIG. 2.

FIG. 4 is a cross-sectional view of a diaphragm-based force-compensated pressure sensor illustrating measurement of pressure, constructed in accordance with another exemplary embodiment of the invention.

FIG. 5 is a cross-sectional view of a cantilever-based force-compensated pressure sensor illustrating measurement of pressure, constructed in accordance with another exemplary embodiment of the invention.

FIG. 6 is a top view of a diaphragm-based pressure sensor illustrating measurement of pressure by measuring change in electric impedance of the soft magnetic material, constructed in accordance with another exemplary embodiment of the invention.

FIG. 7 is a side-view of the diaphragm-based pressure sensor of FIG. 6.

### DETAILED DESCRIPTION OF EXEMPLARY EMBODIMENTS

In accordance with certain aspects of the present technique, pressure sensors that utilize transducers constructed using soft magnetic materials for gauging pressure will be explained below. One example of such a pressure sensor may employ a transducer made from a soft magnetic material (such as a giant stress impedance material). The transducer may be disposed on a spring element, such as but not limited to, a cantilever, a diaphragm, a metallic foil, a beam, a tube, a cylinder, or any structure that can induce stress in the transducer due to its elastic properties. Such a transducer may be used as a strain gauge. The soft magnetic material used to construct the transducer may be partially or entirely a crystalline microstructure, an amorphous microstructure, a nanocrystalline microstructure, or any combination thereof.

Furthermore, the soft magnetic material may include iron, cobalt, or nickel alloys. The alloys formed thereof may comprise combinations of silicon (Si), boron (B), zirconium (Zr), niobium (Nb), copper (Cu), aluminum (Al), molybdenum (Mo), tungsten (W), chromium (Cr), manganese (Mn), phosphorus (P), and carbon (C) in varying proportions. Transducers constructed out of a soft magnetic material, when excited by an electrical signal, may exhibit a large change in impedance even with small changes in stress. This characteristic makes a pressure sensor constructed with the transducer highly sensitive. The electrical signal that may be utilized to excite the soft magnetic material transducer for producing a response may be in the range of about 10 kHz to about 1 GHz. Transducers constructed out of a soft magnetic material may also be disposed in an environment having a magnetic field which may be generated by a magnetic source such as a hard magnetic material or an integrated coil, as will be understood from the following description.

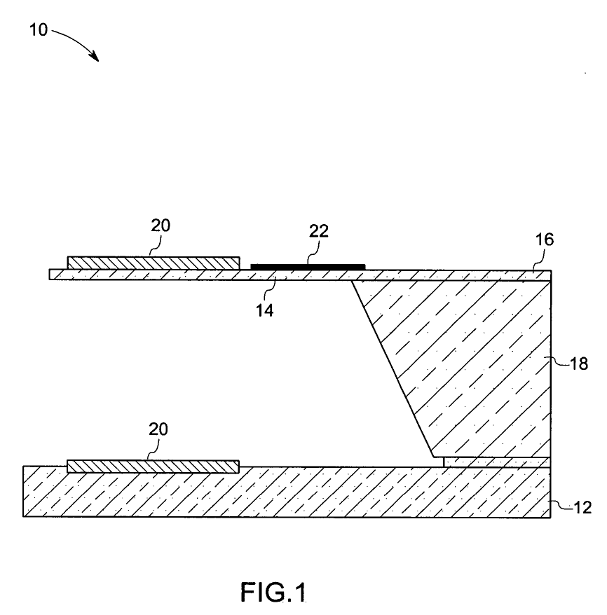

FIG. 1 is a cross-sectional view of an exemplary pressure sensor 10 illustrating a cantilever-based capacitive pressure sensing mechanism. The pressure sensor 10 comprises a substrate 12 on which a cantilever 14 is constructed. A fixed end 16 of cantilever 14 may be disposed on a block 18. The substrate 12 and the block 18 may be micro-machined on an integrated chip or may be constructed directly on a semiconductor substrate. In one embodiment, the pressure sensor 10 may be disposed in a gaseous atmosphere and is subjected to an external magnetic field.

A pair of actuation electrodes 20 may be disposed on the base substrate 12 and the cantilever 14, such that one of the actuation electrodes 20 is positioned on the base substrate 12 while the other is positioned on the cantilever 14; the pair forming the plates of a capacitor, as will be appreciated by one skilled in the art. The actuation electrodes 20 may be coupled electrically with an external circuit that may be utilized to excite or actuate the actuation electrodes. At a given external gaseous atmosphere, and an external magnetic field, the actuation electrodes 20 have a reference resonant frequency. The external circuit may control the electrical resonance occurring in the actuation electrodes 20. At resonant frequencies, the amplitude of the mechanical vibration or motion of the cantilever 14 may be enhanced. A transducer 22 made of a soft magnetic material, may be fabricated on a surface of the cantilever 14, as illustrated. Strain caused in the soft magnetic material transducer 22, because of the mechanical vibration or motion of the overhanging end of the cantilever 14, causes a corresponding change in impedance of the transducer 22. The impedance change of the transducer 22 is an indirect measurement of amplitude of oscillation of the cantilever 14, as the cantilever 14 is driven by the electrostatic actuator or actuation electrode 20 disposed on the base substrate 12.

When the pressure sensor 10 is subjected to an external pressure within the range of about 1 psi to about 30,000 psi, the viscosity of the gas around the cantilever 14 changes. A change in viscosity of the gas affects the resonant frequency of the cantilever 14, so that the resonant frequency of the cantilever 14 shifts from the initial reference resonant frequency to a different resonant frequency. The shift in the resonant frequency may depend on the external pressure to which the cantilever 14 is subjected, because, in a gaseous atmosphere, at a given external magnetic field, the viscosity of the gas may change when the external gas pressure is changed. At resonant frequencies other than the initial reference resonant frequency of the cantilever 14, the magnitude of electrical response produced by the transducer 22 may attain maximum values at frequencies different from the initial reference resonant frequency. This phenomenon enables sensing of the attainment of the different resonant frequencies.

In one embodiment, the soft magnetic material transducer 22 can be extended to cover the entire length of the cantilever 14. Thus, the transducer 22 and the actuation electrode 20, fabricated on the base substrate 12, together form a capacitive pair.

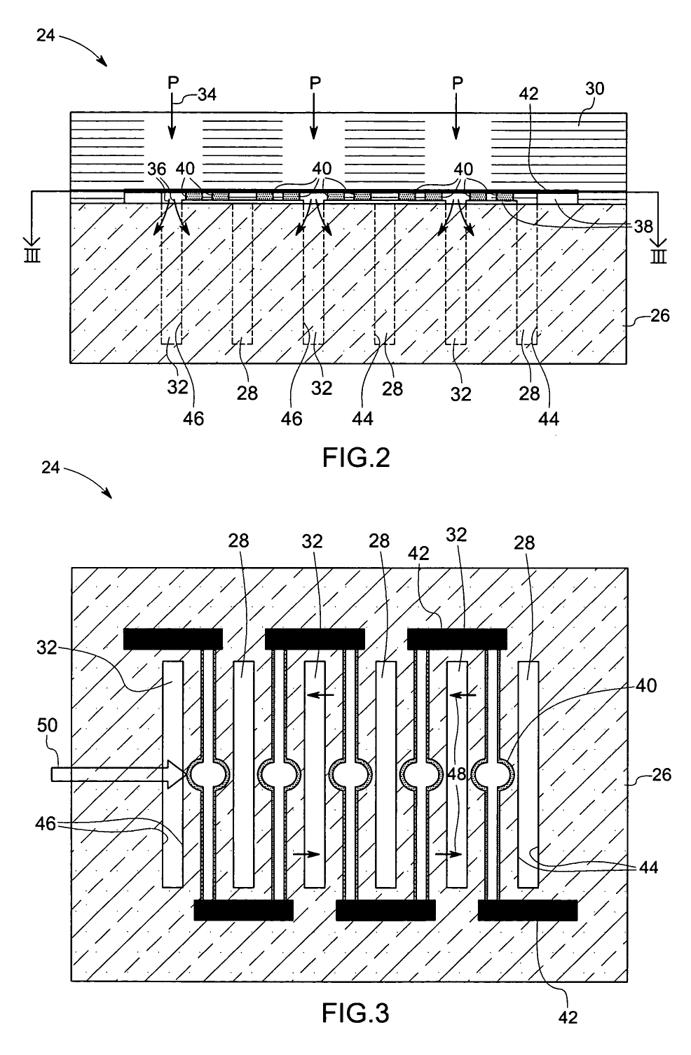

Referring to FIG. 2 and FIG. 3, an exemplary vertical diaphragm pressure sensor array 24 using soft magnetic material transducers for measuring pressure is illustrated. A spring element 26 comprises one or more pressure blind cells 28, which are sealed cavities comprising a gas at a known pressure or a reference pressure. Alternatively, the pressure blind cells 28 may be sealed under vacuum also. The pressure sensor array 24 may be affixed, such as by bonding, to the bottom of the container or vessel that contains gas whose pressure is to be determined. As illustrated in FIG. 2, the pressure sensor array 24 may include a plate 30 to block the pressure blind cells 28 from exposure to the gas under pressure. The plate 30 may be made using a gas impermeable material such as, but not limited to, silicon, silicon carbide, germanium, stainless steel, alumina, aluminum nitride, or the like. The spring element 26 may further include one or more pressure sensitive cells 32 in which the gas whose pressure is to be determined is allowed to enter. As illustrated in FIG. 2, the arrows 34 and 36 indicate the entry of the gas whose pressure is to be determined, into the pressure sensitive cells 32.

A dielectric material 38 may be disposed on a surface of the spring element 26. Transducers 40 are disposed on the dielectric material 38 or directly on the spring element 26. The transducers 40 may include a variety of geometries. For example, the transducers may be radial (as shown in FIG. 3), spiral, serpentine, or straight in shape. The transducers 40 are electrically coupled to connectors 42 that enable powering of the transducers 40. Whenever a gas whose pressure is to be determined is allowed to enter the pressure sensitive cells 32, the pressure developed by the gas in the pressure sensitive cells 32 causes deformation of walls 44 and 46 that enclose, respectively, cells 28 and 32 in the directions indicated by reference numeral 48. The deformation of walls 44 and 46 causes a corresponding horizontal force Fₚ 50 to be reflected on the transducers 40. The horizontal force Fₚ 50 causes the transducers 40 to deform or distort from their original shape, thereby causing a corresponding strain to be developed in the transducers 40. Consequently, the change in impedance of the transducers 40 with respect to the known or reference pressure in the pressure blind cells 28 is indicative of the pressure of the gas that enters the pressure sensitive cells 32.

Another class of pressure sensors in accordance with aspects of the present technique includes force-compensated pressure sensors that employ transducers made from soft magnetic materials, such as stress-impedance materials. Two exemplary types of force-compensated pressure sensors that may be implemented using soft magnetic materials are diaphragm-based force-compensated pressure sensors and cantilever-based force-compensated pressure sensors.

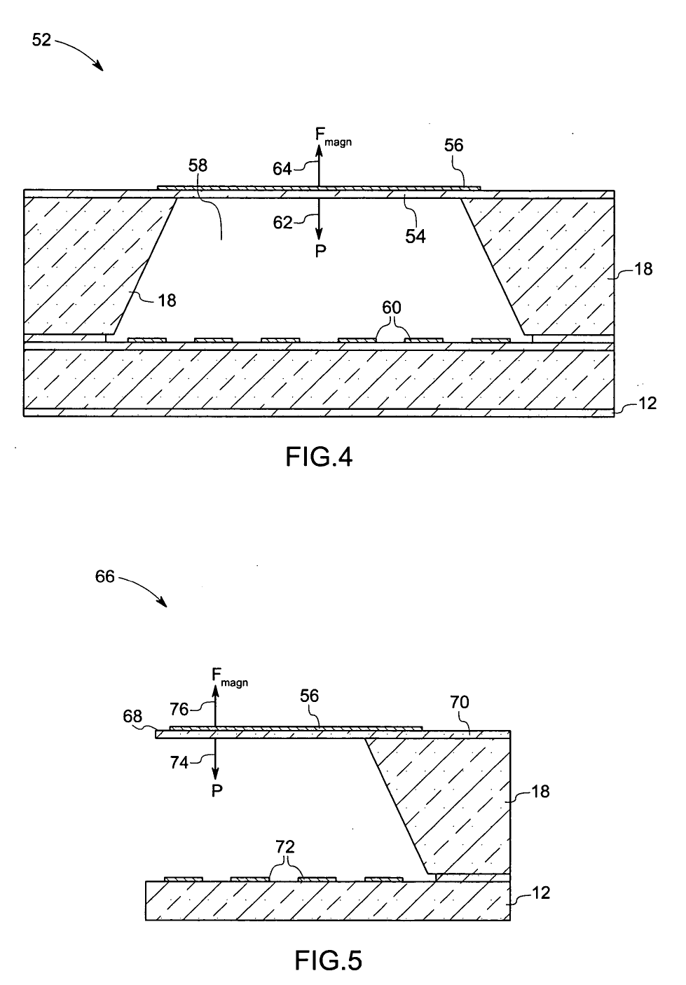

FIG. 4 is a cross-sectional view of an exemplary diaphragm-based force-compensated pressure sensor 52. The diaphragm-based force-compensated pressure sensor 52 has a diaphragm 54 that is formed on blocks 18, which are in turn formed on a substrate 12. On one surface of the membrane that forms the diaphragm 54, a thin layer of soft magnetic material 56, such as a stress-impedance material is disposed. The thin layer of soft magnetic material 56 may be a part of the diaphragm 54. Defined by substrate 12, blocks 18 and diaphragm 54 is a cavity 58 that is filled with a fluid such as air or an inert gas. An integrated coil 60 may be disposed on a surface of the substrate 12. The integrated coil 60 is utilized to provide an opposing force to the force developed when the diaphragm 54 is subjected to external pressure. The integrated coil 60 may be fabricated using an electrically conductive material such as copper, aluminum, or other electrically conductive metals.

When the pressure sensor assembly 52 is subjected to an external pressure, the force developed by the pressure 62 deflects the magnetic structure or soft magnetic material 56 in a direction perpendicular to the plane of diaphragm 54, such that the diaphragm 54 will deflect up or down. An electrical signal is fed into the integrated coil 60 so that a magnetic force F_{magn} 64 is developed in soft magnetic material 56. The electrical signal that is fed into integrated coil 60 is modulated so as to compensate for the force developed by the pressure 62. For example, if the force due to pressure 62 causes diaphragm 52 deflect downwards, the electrical signal fed into integrated coil 60 may be modulated so that magnetic force F_{magn} 64 developed in soft magnetic material 56 will cause diaphragm 54 to move up to compensate for the force developed by pressure 62. Similarly, if the force attributable to pressure 62 causes diaphragm 54 to deflect upwards, the electrical signal fed into integrated coil 60 may be modulated so that magnetic force F_{magn} 64 developed in soft magnetic material 56 will cause diaphragm 54 to move down.

A measure of the electrical signal fed into integrated coil 60 for compensation of the force due to pressure 62 will therefore be indicative of the amount of pressure applied to the pressure sensor assembly. Thus, the amount of electrical signal may be modulated to provide a compensative magnetic force F_{magn} 64 and the same may be calibrated to read the pressure applied.

FIG. 5 is a cross-sectional view of an exemplary cantilever-based force-compensated pressure sensor 66. The cantilever-based force-compensated pressure sensor assembly 66 may be constructed on a substrate 12. A cantilever 68 is disposed such that a fixed end 70 of the cantilever 68 is positioned on a block 18. Substrate 12, block 18, and cantilever 68 may be constructed via micro-machining techniques known in the art.

A thin layer of soft magnetic material 56 may be disposed on cantilever 68, while an integrated coil 72 may be disposed on the substrate 12. Once an external pressure is applied to the cantilever 68, the force 74 that is developed due to the pressure will cause the cantilever 68 to vibrate in a direction perpendicular to the plane in which cantilever 68 resides. An electrical signal may be fed into integrated coil 72 so that a magnetic force F_{magn} 76 is developed in soft magnetic material 56 overlying cantilever 68. The electrical signal that is fed into integrated coil 72 may be modulated to compensate for the force 74. For example, if the force 74 causes cantilever 68 to deflect downwards, the electrical signal fed into integrated coil 72 may be modulated so that magnetic force F_{magn} 76 developed in soft magnetic material 56 will cause cantilever 68 to move up so as to compensate for the force developed by pressure 74. The magnitude of electrical signal that is fed into integrated coil 72 for compensation of the force due to pressure 74 may therefore be utilized as a measure for the external pressure applied to pressure sensor assembly 66.

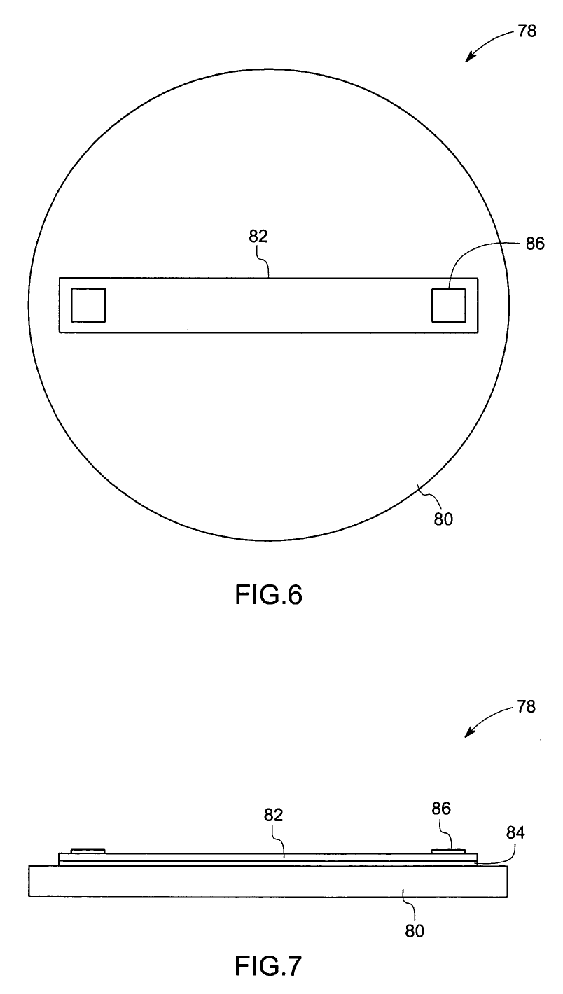

Referring to FIG. 6 and FIG. 7, an exemplary diaphragm-based pressure sensor 78 is illustrated. The diaphragm-based pressure sensor 78 comprises a diaphragm 80 that may be fabricated or micro-machined on a substrate (not shown). On a top surface of the diaphragm 80, a thin layer of soft magnetic material 82, such as a stress-impedance material, may be disposed. If the diaphragm 80 is constructed out of an electrically conducting material, then a layer of an insulating material 84 may be used to isolate the soft magnetic material from the diaphragm 80. The insulating material 84 may also serve as a bonding material between the diaphragm 80 and the layer of soft magnetic material 82. The layer of soft magnetic material 82 may be connected to an electrical signal/circuit via electrical connectors 86.

In one embodiment, the insulating or bonding material 84 may be disposed on the diaphragm 80 below the ends of the soft magnetic material 82 where electrical connections 86 are made. In another embodiment, the insulating or bonding material 84 may be disposed in a ring pattern such that the soft magnetic material 82 rests above the bonding material 84 and may be connected by electrical connectors 86. In a different embodiment, the diaphragm 80 may be modeled such that the soft magnetic material 82 may not be completely in contact with the surface of the diaphragm 80.

When the pressure sensor 78 is subjected to an external pressure, the force developed by the pressure deflects the diaphragm 80 and soft magnetic material 82 in a direction perpendicular to the plane in which the diaphragm 80 resides. Therefore, the diaphragm 80 will deflect up or down. An AC current is delivered to the soft magnetic material 82. As the soft magnetic material 82 deflects, the stress developed in the soft magnetic material 82 produces a change in the impedance of the soft magnetic material 82. A measure of the change in amplitude of impedance or phase angle of the change in impedance of soft magnetic material 82 may therefore be indicative of the amount of pressure applied to the pressure sensor 78.

Because soft magnetic materials, such as stress-impedance materials, exhibit a large change in impedance when the material is subjected to a small amount of stress, the sensitivity of the materials in detecting stress is very high. The application of soft magnetic materials in gauging input signals or stimulating forces such as pressure, force, motion, mechanical vibration or the like by utilizing this property of the material is advantageous. The teachings of the present techniques may be applicable for gauging force, motion, mechanical vibration, weight, position, acceleration, or the like in addition to pressure, by modifications to the described embodiments that would be apparent to one of ordinary skill in the art.

Those of ordinary skill in the art will appreciate that strain gauges or transducers constructed using soft magnetic materials in accordance with aspects of the present technique may be arranged in a wide array of geometric patterns depending upon the specific application. For example, the strain gauges may be arranged in a rectangular pattern as illustrated in FIG. 1 and FIG. 6, or radial pattern as illustrated in FIG. 3. Other geometric patterns may also be used, such as but not limited to, a spiral pattern, a serpentine pattern, a rectangular pattern, a ring, a disc, an arc and other patterns formed by connecting strips of soft magnetic material strain gauges together that would enable the measurement of strains in specific directions. Furthermore, the soft magnetic material may be constructed to provide the functionalities of a spring element.

In all the embodiments noted above, the substrate 12 and the block 18 may be micro-machined on an integrated chip using semiconductor materials such as, but not limited to, silicon (Si), silicon nitride (SiNₓ), indium phosphate (InP), gallium arsenide (GaAs), silicon-germanium (Si—Ge), silicon oxide (SiO₂), silicon carbide (SiC) and gallium nitride (GaN), germanium; metals or metallic alloys such as stainless steel, inconel, aluminum; ceramic materials such as quartz, sapphire (Al₂O₃), or any other semiconductor material or metallic alloys known in the art to be suitable for micro-machining. Similarly, the cantilevers 14 and 68 may be constructed using materials such as but not limited to, silicon, silicon nitride, silicon-germanium, aluminum, gold, titanium, chromium, or using a dielectric material, or materials having high elasticity such as stainless steel. The diaphragm 26, 54 and 80 may comprise a thin membrane made of a semiconductor material such as silicon, silicon nitride, metals and metal alloys such as stainless steel, titanium, hastelloy, ceramics or other materials with desirable mechanical properties, such as high elasticity, fatigue resistance, etc. One example of a dielectric material that may be used is a polyimide film, such as KAPTON® that is commercially available from E. I. DuPont De Nemours and Company of Wilmington, Del.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

1. A sensor for measuring an input signal, comprising:
a transducer comprising a soft magnetic material disposed on a spring element, the transducer adapted to produce an impedance change when stimulated by the input signal, wherein the impedance change is representative of a magnitude of the input signal; and
a circuit coupled to the transducer, wherein the circuit is operable to measure the impedance change to determine the magnitude of the input signal.

2. The sensor of claim 1, wherein the input signal comprises at least one of pressure, motion, weight, position, acceleration, mechanical force, and mechanical vibration.

3. The sensor of claim 1, wherein the soft magnetic material comprises a stress-impedance material.

4. The sensor of claim 1, wherein the soft magnetic material comprises an amorphous soft magnetic material.

5. The sensor of claim 4, wherein the amorphous soft magnetic material comprises nano-scale crystallites.

6. The sensor of claim 1, wherein the soft magnetic material is an alloy, the alloy primarily comprising iron.

7. The sensor of claim 6, wherein the alloy comprises cobalt.

8. The sensor of claim 1, wherein the spring element is operable to transmit a strain induced by the input signal to the soft magnetic material.

9. The sensor of claim 1, wherein the spring element is operable to produce a deflection when stimulated by the input signal, and wherein the spring element comprises one of a diaphragm, a cantilever, a foil, a beam, a tube, a cylindrical structure, at least one pressure blind signal, or any combinations thereof.

10. The sensor of claim 1, comprising a strain gauge operable to reflect the impedance change.

11. The sensor of claim 10, wherein the strain gauge comprises a configuration from one of a spiral configuration, a serpentine configuration, a rectangular configuration, a ring configuration, a disc configuration, or an arc configuration.

12. A sensor for measuring an input signal, comprising:
a transducer comprising a soft magnetic material disposed on a spring element, wherein the transducer is in a magnetic field generated by a magnetic source, the soft magnetic material being adapted to produce an impedance change representative of a magnitude of the input signal when the transducer is stimulated by the input signal; and
a circuit coupled to the transducer, wherein the circuit is operable to measure the impedance change to determine the magnitude of the input signal.

13. The sensor of claim 12, wherein the input signal comprises at least one of pressure, motion, weight, position, acceleration, mechanical force, and mechanical vibration.

14. The sensor of claim 12, wherein the magnetic source comprises a hard magnetic material.

15. The sensor of claim 12, wherein the magnetic source comprises an integrated coil.

16. The sensor of claim 12, wherein the soft magnetic material comprises an amorphous soft magnetic material.

17. The sensor of claim 16, wherein the amorphous soft magnetic material comprises nano-scale crystallites.

18. The sensor of claim 12, wherein the soft magnetic material is an alloy, the alloy primarily comprising iron.

19. The sensor of claim 18, wherein the alloy primarily comprises cobalt.

20. The sensor of claim 12, wherein the spring element is operable to transmit a strain induced by the input signal to the soft magnetic material.

21. The sensor of claim 12, wherein the spring element is operable to produce a deflection when stimulated by the input signal, and wherein the spring element comprises one of a diaphragm, a cantilever, a foil, a beam, a cylindrical structure, at least one pressure blind signal, or any combinations thereof.

22-47. (canceled)

48. A method of manufacturing a sensor, the method comprising:
providing a transducer that comprises a soft magnetic material disposed on a spring element, the transducer being adapted to produce an impedance change representative of a magnitude of an input signal; and
coupling a circuit to the transducer, the circuit being operable to measure the impedance change to determine the magnitude of the input signal.
